(19) United States
(12) Patent Application Publication
(10) Pub. No.: US 2021/0276231 A1
(43) Pub. Date: Sep. 9, 2021

(54) DETERMINATION METHOD, IMPRINT METHOD, IMPRINT APPARATUS, ARTICLE MANUFACTURING METHOD AND NON-TRANSITORY STORAGE MEDIUM

(71) Applicant: CANON KABUSHIKI KAISHA, Tokyo (JP)

(72) Inventor: Takahiro Sato, Tochigi (JP)

(21) Appl. No.: 17/166,928

(22) Filed: Feb. 3, 2021

(30) Foreign Application Priority Data
Mar. 6, 2020 (JP) 2020-039217

(51) Int. Cl. B29C 43/56; H01L 21/28; G03F 7/00

(52) U.S. Cl. CPC B29C 43/56; B29C 2043/563; G03F 7/0002; H01L 21/28123

(57) ABSTRACT

The present invention provides a determination method of determining a drop pattern indicating a layout of droplets of an imprint material to be arranged on a substrate and used in an imprint apparatus which forms a pattern of the imprint material on the substrate by using a mold, the method including obtaining a contact start position at which the mold comes first into contact with the imprint material in a partial shot region on the substrate based on a posture of the mold, and determining a drop pattern in the partial shot region so as to arrange droplets of the imprint material at a plurality of positions respectively located along a plurality of different radiation directions from the contact start position, with the obtained contact start position serving as a starting point.

### BACKGROUND OF THE INVENTION

### Field of the Invention

The present invention relates to a determination method, an imprint method, an imprint apparatus, an article manufacturing method, and a non-transitory storage medium.

### Description of the Related Art

An imprint technique is a technique of transferring the pattern of a mold to a substrate by bringing the mold into contact with an imprint material on the substrate, filling a concave portion forming the pattern of the mold with the imprint material, and then curing the imprint material, as disclosed in Japanese Patent Laid-Open Nos. 2009-536591 and 2017-103399.

Japanese Patent Laid-Open No. 2009-536591 discloses a technique of deforming a mold in a convex shape toward a substrate, bringing the central portion of the mold into contact with an imprint material (polymer material) on the substrate, and then enlarging the contact region between the imprint material and the mold. In this technique, in the process of enlarging the contact region between an imprint material and a mold, gas present between the substrate and the mold is discharged.

Japanese Patent Laid-Open No. 2017-103399 discloses a technique of deforming a substrate in a convex shape toward a mold and bringing the mold into contact with an imprint material on the substrate in a shot region on the periphery of the substrate. Japanese Patent Laid-Open No. 2017-103399 also discloses a technique of tilting and bringing a mold into contact with an imprint material in a shot region on the periphery of a substrate.

In the process of enlarging the contact region between an imprint material on a substrate and a mold, the gas confined in the space surrounded by the substrate, the mold, and the imprint material hinders the filling of the pattern (concave portion) of the mold with the imprint material. Curing the imprint material while the tilling of the pattern of the mold with the imprint material is incomplete may cause a failure (defect) in the pattern formed by the cured imprint material. Accordingly, the start of curing of the imprint material needs to be waited until the gas confined in the space surrounded by the substrate, the mold, and the imprint material is dissolved or condensed in the imprint material and disappears, and the pattern of the mold is filled with the imprint material. Such a process reduces the throughput of the imprint apparatus. The confinement of the gas occurs when a path for discharging the gas is clogged with the imprint material, and hence it is important how to arrange the imprint material on the substrate.

The shot regions within a substrate, to which the pattern of a mold is transferred, are roughly classified into two types, namely full shot regions equal in size to the mold and partial shot regions smaller in size than the mold. In order to obtain more chips from a substrate, it is necessary to perform an imprint process for even partial shot regions on the periphery of the substrate. Note, however, that the technique disclosed in Japanese Patent Laid-Open No. 2017-103399 needs to be used for partial shot regions. This technique greatly differs in the contact point between a mold and a substrate and a filling path for an imprint material from the technique used for full shot regions. Accordingly, the arrangement of an imprint material which is optimized for full shot regions is not necessarily optimal for partial shot regions. Arranging an imprint material for partial shot regions based on the same idea as that for full shot regions may lead to the confinement of gas upon filling with an imprint material and a decrease in throughput. For this reason, it is important how to arrange an imprint material on a substrate, for each shot region on the substrate, in accordance with the positions, postures, and shapes of the mold and the substrate.

### SUMMARY OF THE INVENTION

The present invention provides a technique advantageous in determining a drop pattern in a partial shot region.

According to one aspect of the present invention, there is provided a determination method of determining a drop pattern indicating a layout of droplets of an imprint material to be arranged on a substrate and used in an imprint apparatus which forms a pattern of the imprint material on the substrate by using a mold, the method including specifying a partial shot region of the plurality of shot regions which has a smaller area than a pattern region of the mold based on a layout of a plurality of shot regions on the substrate, determining a posture of the mold when the mold is brought into contact with the imprint material arranged in the partial shot region specified in the specifying, obtaining a contact start position at which the mold conies first into contact with the imprint material in the partial shot region based on the posture of the mold determined in the determining the posture, and determining the drop pattern in the partial shot region so as to arrange droplets of the imprint material at a plurality of positions respectively located along a plurality of different radiation directions from the contact start position, with the contact start position obtained in the obtaining serving as a starting point.

Further aspects of the present invention will become apparent from the following description of exemplary embodiments with reference to the attached drawings.

### BRIEF DESCRIPTION OF THE DRAWINGS

FIG. 1 is a schematic view illustrating configurations of an imprint apparatus as one aspect of the present invention.

FIG. 2 is a schematic view illustrating configurations of an imprint apparatus as one aspect of the present invention.

FIGS. 3A and 3B are views illustrating an example of the configurations of a substrate holding unit.

FIG. 4 is a view illustrating an example of the configurations of a mold driving unit.

FIG. 5 is a view for describing an imprint process for a full shot region.

FIG. 6 is a view for describing an imprint process for a partial shot region.

FIG. 7 is a view for describing an imprint process for a partial shot region.

FIG. 8 is a view for describing the relationship between the layout of droplets of an imprint material and a contact start position.

FIG. 9 is a view for describing the relationship between the layout of droplets of an imprint material and a contact start position.

FIG. 10 is a flowchart for describing a determination method of determining a drop pattern.

FIG. 11 is a flowchart for describing a determination method of determining a drop pattern.

FIG. 12A to FIG. 12F are views for describing an article manufacturing method.

### DESCRIPTION OF THE EMBODIMENTS

Hereinafter, embodiments will be described in detail with reference to the attached drawings. Note, the following embodiments are not intended to limit the scope of the claimed invention. Multiple features are described in the embodiments, but limitation is not made to an invention that requires all such features, and multiple such features may be combined as appropriate. Furthermore, in the attached drawings, the same reference numerals are given to the same or similar configurations, and redundant description thereof is omitted.

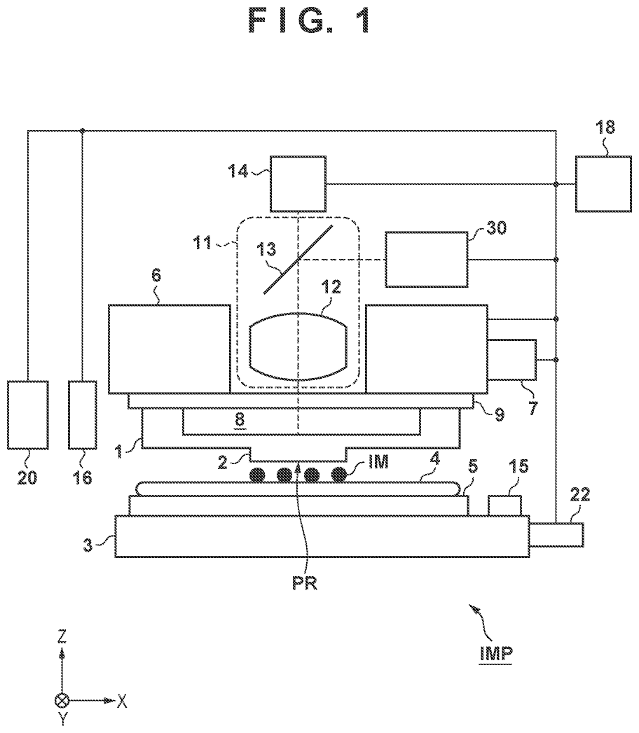

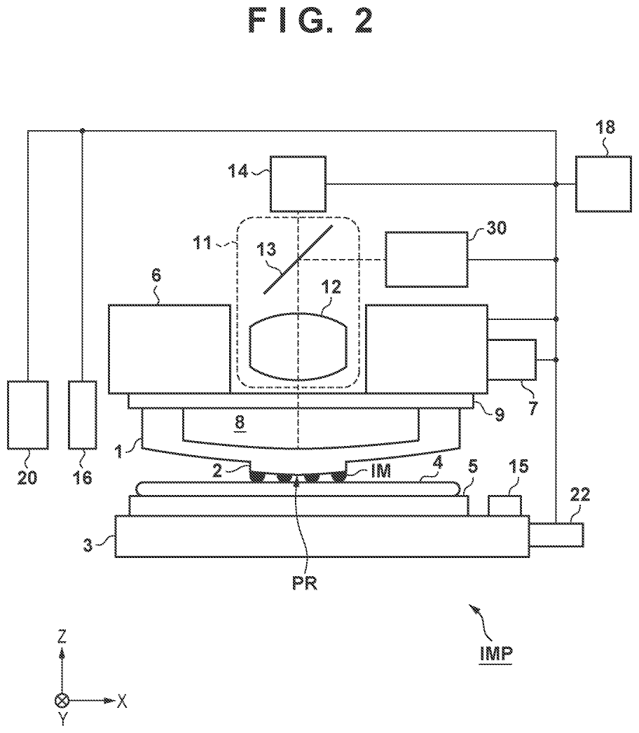

FIGS. 1 and 2 are schematic views illustrating the configurations of an imprint apparatus IMP as one aspect of the present invention. The imprint apparatus IMP is a lithography apparatus that is used for a lithography step as a manufacturing step for a device such as a semiconductor device, liquid crystal display device, or magnetic storage medium as an article and forms a pattern on a substrate. The imprint apparatus IMP brings a mold into contact with an uncured imprint material supplies onto a substrate and applies curing energy to the imprint material, thereby forming a pattern of the cured imprint material to which the pattern of the mold is transferred.

As the imprint material, a curable composition (to be also referred to as a resin in an uncured state) to be cured by receiving curing energy is used. An example of the curing energy that is used is electromagnetic waves and the like. As the electromagnetic waves, for example, infrared light, visible light, ultraviolet light, and the like selected from the wavelength range of 10 nm (inclusive) to 1 mm (inclusive) is used.

The curable composition is a composition cured by light irradiation. The photo-curable composition cured by light irradiation contains at least a polymerizable compound and a photopolymerization initiator, and may contain a nonpolymerizable compound or a solvent, as needed. The nonpolymerizable compound is at least one type of material selected from a group comprising of a sensitizer, a hydrogen donor, an internal mold release agent, a surfactant, an antioxidant, a polymer component, and the like.

The imprint material may be applied in a film shape onto the substrate by a spin coater (spin coating, method) or a slit coater (slit coating method). The imprint material may be applied, onto the substrate, in a droplet shape or in an island or film shape formed by connecting a plurality of droplets using a liquid injection head. The viscosity (the viscosity at 25° C.) of the imprint material is, for example, 1 mPa·s (inclusive) to 100 mPa·s (inclusive).

As the substrate, glass, ceramic, a metal, a semiconductor, a resin, or the like is used, and a member made of a material different from that of the substrate may be formed on the surface of the substrate, as needed. More specifically, examples of the substrate include a silicon wafer, a semiconductor compound wafer, silica glass, and the like.

The imprint apparatus IMP performs an imprint process of forming the pattern of an imprint material on a substrate by using a mold. An imprint process includes an arrangement step, a contact step executed after the arrangement step, a curing step executed after the contact step, and a separation step executed after the curing step. In an arrangement step, an imprint material IM is arranged in a droplet state on a shot region on a substrate 4. In a contact step, a pattern region PR of a mold 1 is brought into contact with the imprint material IM (its droplets) on part of a shot region on the substrate 4, and the contact region between the imprint material IM and the pattern region PR is enlarged over the entire shot region. In a curing step, the imprint material IM is cured while the imprint material IM on the shot region on the substrate 4 is in contact with the patters region PR of the mold 1. In a separation step, the cured imprint material IM on the shot region on the substrate 4 is separated from the pattern region PR of the mold 1.

In the specification and the accompanying drawings, directions will be indicated on an XYZ coordinate system in which directions parallel to the surface of a substrate 4 are defined as the X-Y plane. Directions parallel to the X-axis, the Y-axis, and the Z-axis of the XYZ coordinate system are the X-direction, the direction, and the Z direction, respectively. A rotation about the X-axis, a rotation about the Y-axis, and a rotation about the Z-axis are θX, θY, and θZ, respectively. Control or driving (moving) concerning the X-axis, the Y-axis, and the Z-axis means control or driving concerning at direction parallel to the X-axis, a direction parallel to the Y-axis, and a direction parallel to the Z-axis, respectively. In addition control or driving (moving) concerning the θX-axis, the θY-axis, and the θZ-axis means control or driving concerning a rotation about an axis parallel to the X-axis, a rotation about an axis parallel to the Y-axis, and rotation about an axis parallel to the Z-axis, respectively. In addition, a position is information that is specified based on coordinates on the X-, Y-, and Z-axes, and a posture is information that is specified by values on the θX-, θY-, θZ-axes. Positioning means controlling the position and/or the posture. Alignment includes. controlling the position and the of art least one of the substrate 4 and the mold 1. In addition, alignment includes controlling for correcting or changing the shape of at least one of the substrate 4 and the mold 1.

The imprint apparatus IMP includes a substrate holding unit 5 that holds the substrate 4, a substrate driving unit 3 that drives the substrate 4 by driving the substrate holding unit 5, and a substrate deformation unit 22 that deforms the substrate 4.

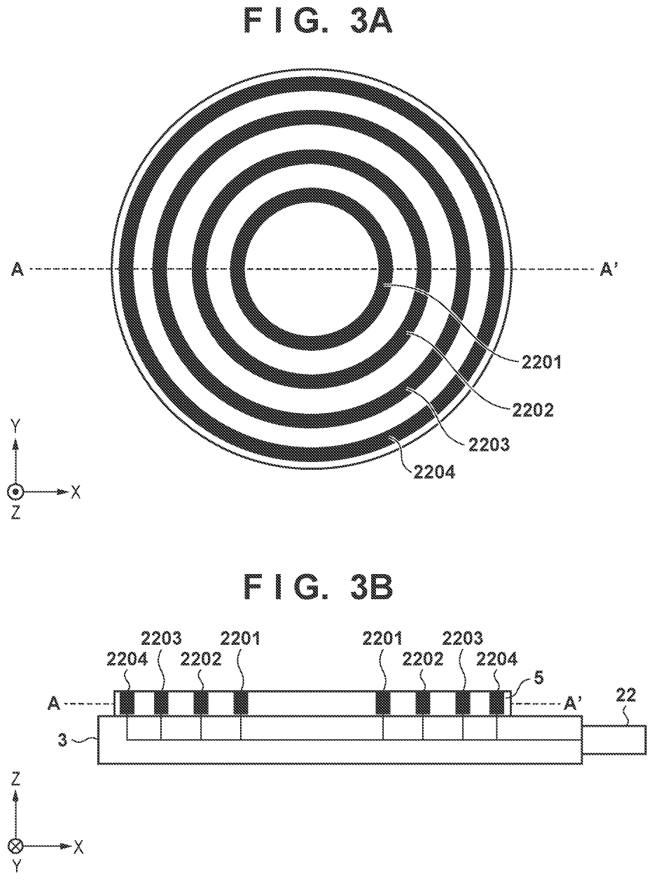

As shown in FIGS. 3A and 3B, the substrate holding unit 5 includes a plurality of holding regions (segmented portions) that hold (suck) the substrate 4, namely four holding regions 2201, 2202, 2203, and 2204 in this embodiment. FIG. 3A is an XY plane view illustrating the configurations of the substrate holding unit 5. FIG. 3B is a sectional view taken along A-A′ of the substrate holding unit 5 illustrated in FIG. 3A.

The substrate deformation unit 22 deforms the substrate 4 by controlling the respective holding forces of the four holding regions 2201, 2202, 2203, and 2204 of the substrate holding unit 5. In this embodiment, the substrate deformation unit 22 controls suction and repulsion with respect to the substrate 4 for each of the holding regions 2201, 2202, 2203, and 2204, and controls the Z-direction position of the substrate 4, that is, the shape of the substrate 4 with respect to the mold 1, for each holding region by combining suction and repulsion. In this case, repulsion with respect to the substrate 4 means that each of the holding, regions 2201, 2202, 2203, and 2204 applies a positive pressure to the substrate 4 (its lower surface).

For example, the substrate holding unit 5 is controlled to suck the substrate 4 with the holding regions 2201, 2202, and 2204 and to repel the substrate 4 with the holding region 2203. This makes it possible to deform part of the substrate 4 (a portion on the holding region 2203) in a convex shape. Such control is effective especially when the pattern region PR of the mold 1 is brought into contact with the imprint material IM arranged in a partial shot region of the substrate 4. More specifically, it is possible to bring the pattern region PR into contact with the imprint material IM without bringing the mold 1 (its pattern region PR) into contact with an outermost peripheral region of a partial shot region on which the imprint material IM is not arranged. In this case, a partial shot region is a shot region of the plurality of shot regions on the substrate which has a smaller area than the pattern region PR of the mold 1. A full shot region is a shot region of the plurality of shot regions on the substrate which has the same area as that of the pattern region PR of the mold 1.

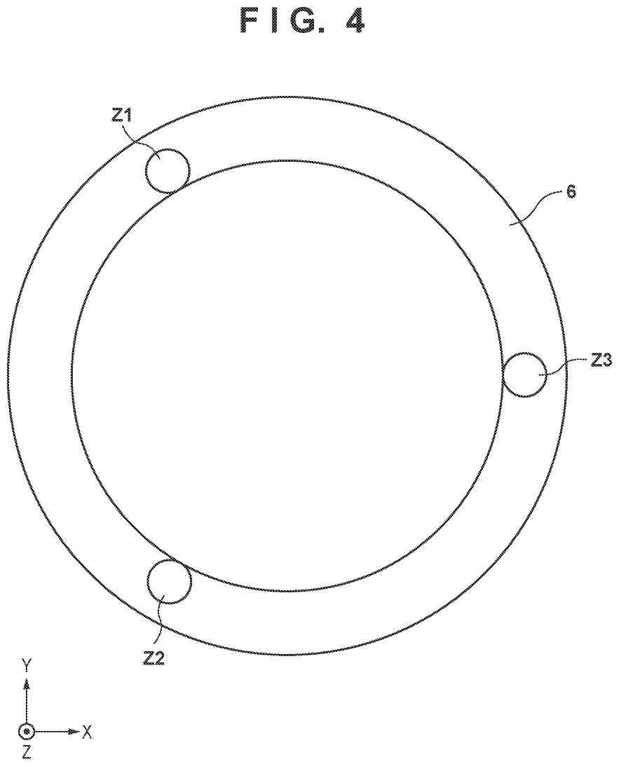

The imprint apparatus IMP includes a mold holding unit 9 that holds the mold 1 and a mold driving unit 6 that drives the mold 1 by driving the mold holding unit 9. As shown in FIG. 4, the mold driving unit 6 includes three driving systems Z1, Z2, and Z3 that drive the mold holding unit 9 in the Z direction. The driving systems Z1, Z2, and Z3 include sensors that detect a position in the Z-axis direction and an action in the Z direction, and controls the position and posture of the mold 1, the force applied to the mold 1, and the like based on outputs from the sensors. FIG. 4 is an XY plane view illustrating the configurations of the mold driving unit 6.

For example, the mold 1 can be tilted in the +X direction by pushing the mold 1 in the −Z direction (toward the substrate 4) with the driving systems Z1 and Z2 and pushing the mold 1 in the +Z direction with the driving system Z3. Such control is effective especially when the pattern region PR of the mold 1 is brought into contact with the imprint material IM arranged in a partial shot region on the substrate 4. More specifically, it is possible to bring the pattern region PR into contact with the imprint material IM without bringing the mold 1 (its pattern region PR) into contact with the outermost peripheral region of the partial shot region on which the imprint material IM is not arranged.

The substrate driving unit 3 and the mold driving unit 6 constitute a driving mechanism that drives at least one of the substrate 4 and the mold 1 so as to adjust the relative position between the substrate 4 (a shot region) and the mold 1 (the pattern region PR). The adjustment of the relative position between the substrate 4 and the mold 1 by this driving mechanism includes driving operations for bringing the pattern region PR of the mold 1 into contact with the imprint material on the substrate 4 and separating the mold 1 from the cured imprint material IM on the substrate 4. The substrate driving a unit is configured to drive the substrate 4 along a plurality of axes (for example, three axes, namely the X-axis, the Y-axis, and the θZ-axis, preferably six axes, namely the X-axis the Y-axis, the Z-axis, the θX-axis, the θY-axis, and the θZ-axis). The mold driving unit 6 is configured to drive the mold 1 along a plurality of axes (for example, three axes, namely the Z-axis, the θX-axis, and the θY-axis, preferably six axes, namely the X-axis, the Y-axis, the Z-axis, the θX-axis, the θY-axis, and the θZ-axis).

The imprint apparatus IMP includes a curing unit 30 that cures the imprint material IM by applying curing energy to the imprint material IM on a substrate (on a shot, region) and an image capturing unit 14 that can capture (observe) an image of a visual field including the pattern region PR of the mold 1. The imprint apparatus IMP also includes an alignment measuring system (not shown) that measures the relative position between a shot region on the substrate 4 and the pattern region PR of the mold 1.

The curing unit 30 is configured to provide curing energy to the imprint material IM via an optical system 11. The optical system 11 includes, for example, a relay optical system 12 and a mirror 13.

The image capturing unit 14 captures an image of a visual field including the pattern region PR of the mold 1 via the optical system 11. The image capturing unit 14 captures, for example, an image depicting the contact point between the imprint material IM on the substrate and the pattern region PR of the mold 1 and bow the contact region between the imprint material IM and the pattern region PR enlarges (the temporal change of the filling path for the imprint material IM) in a contact step. The image capturing unit 14 also captures a fringe image formed by the gap between the mold 1 (pattern region PR) and the substrate 4.

The has a first side and a second side. The first side of the mold 1 is provided with a mesa portion 2 protruding from a peripheral portion. The surface of the mesa portion 2 is provided with the pattern region PR on which a pattern to be transferred to the substrate 4 is formed. On the other hand, the second side of the mold 1 is provided with a cavity 8. Applying a pressure (force) to the cavity 8 can deform the mesa portion 2 of the mold 1 and the pattern region PR. The deformation of the mesa portion 2 and the pattern region PR in the Z direction includes forming the mesa portion 2 and the pattern region PR in a convex shape toward the substrate 4 and in a flat shape.

The imprint apparatus IMP includes a cavity deformation unit 7 that controls the deformation of the mesa portion 2 of the mold 1 and the pattern region PR in the Z direction h controlling the pressure applied to the cavity 8. The imprint apparatus IMP also includes a deformation mechanism (not shown) that changes the shape of the pattern region PR within a plane parallel to an XY plane (the shape of the pattern region PR which is projected on an XY plane) by applying a force to the first side surface.

The imprint apparatus IMP includes a mold measuring unit 15 that measures the height and tilt amount (θX, θY) of the pattern region PR of the mold 1 and a substrate measuring unit 16 that measures the height and tilt amount (θX, θY) of the surface of the substrate 4. The mold measuring unit 15 is driven together with the substrate holding unit 5 by, for example, the substrate driving unit 3.

The imprint apparatus IMP includes a dispenser 20 that arranges the imprint material IM in a droplet state on the substrate 4. The dispenser 20 arranges droplets of the imprint material IM on the substrate in accordance with a drop pattern indicating the layout of the droplets of the imprint material IM which are to be arranged on the substrate under the control of a control unit 18. The dispenser 20 may be understood as an arranging unit that arranges the imprint material IM on the substrate 4 or a supply unit (coating unit) that supplies (coats) the imprint material IM onto the substrate 4.

The imprint apparatus IMP includes the control unit 18 that controls the substrate driving unit 3, the mold driving unit 6, the curing unit 30, the image capturing unit 14, the mold measuring unit 15, the substrate measuring unit 16, the dispenser 20, and the like. The control unit 18 is constituted by, for example, a PLD (the abbreviation of a Programmable Logic Device) such as an FPGA (the abbreviation of a Field Programmable Gate Array), an ASIC (the abbreviation of an Application Specific Integrated Circuit), a general or dedicated computer incorporating programs, or a combination of all or some of these constituent elements.

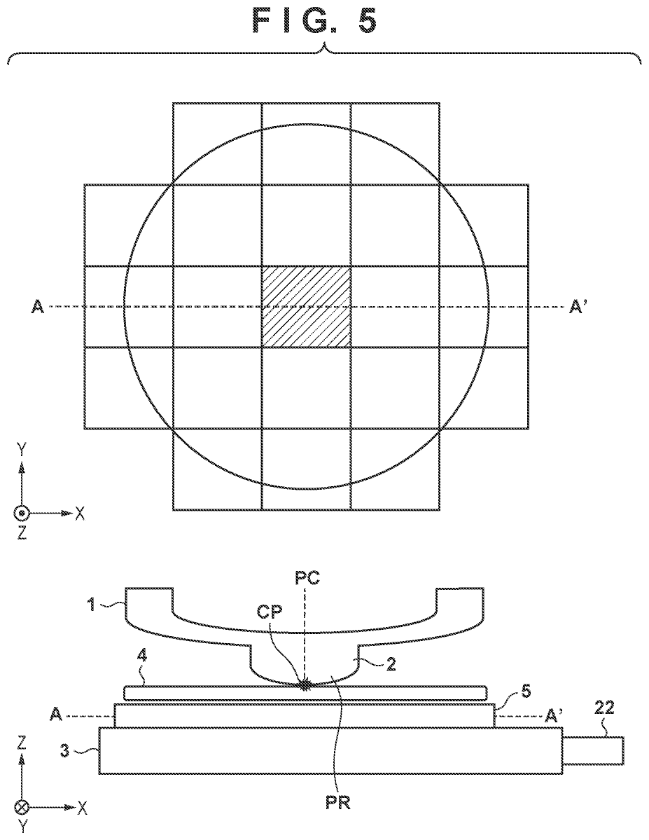

Described below is about the difference between an imprint process for a full shot region and an imprint process for a partial shot region. FIG. 5 illustrates how an imprint process is performed for a full shot region, more specifically, how a contact step is performed to bring the pattern region PR of the mold 1 into contact with the imprint material IM on a full shot region on a substrate. As shown in FIG. 5, in a contact step in an imprint process for a full shot region, the substrate 4 is generally held by the four holding regions 2201 to 2204 of the substrate holding unit 5. Accordingly, in a contact step in an imprint process for a full shot region, although the position and posture of the substrate 4 with respect to the pattern region PR of the mold 1 are controlled, the substrate holding unit. does not intentionally change the shape of the substrate 4 (the position in the Z direction). With regard to the mold 1 in order to prevent gas from being confined in the space surrounded by the substrate 4, the imprint material IM, and the mold 1, a pressure is applied to the cavity 8 to change the pattern region PR into a convex shape in the −Z direction (toward the substrate 4). In such a state, when the pattern region PR of the mold 1 is brought into contact with the imprint material IM on the full shot region, a contact start position CP at which the pattern region PR comes first into contact with the imprint material IM coincides with (matches) a pattern central position PC of the pattern region PR. Note that even if the contact start position CP is shifted from the pattern central position PC, because the shift amount is small as compared with the partial shot region, common contact conditions and the arrangement of the imprint material IM are effective between full shot regions. In addition, the manner of how the contact region between the imprint material IM and the pattern region PR enlarges over the entire full shot region, that is, the time-series change of the contact region (the filling path for the imprint material IM), is the same as that between full shot regions. This is because many full shot regions are laid out on a relatively flat portion of the, substrate 4 and are held by a relatively flat portion of the substrate holding unit 5.

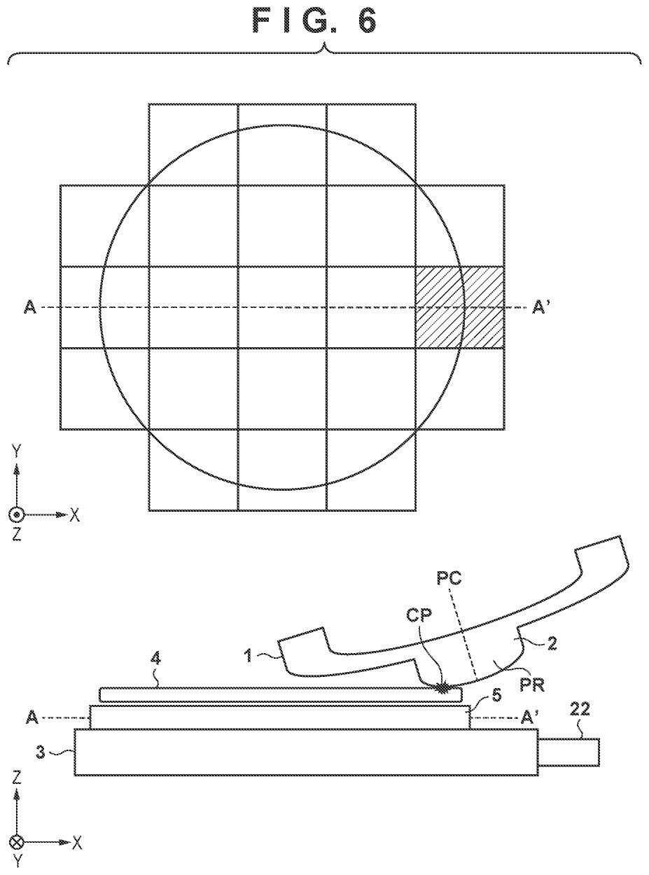

In contrast, in an imprint process for a partial shot region, the pattern central position PC is not sometimes present in the partial shot region in a contact step of bringing the pattern region PR of the mold 1 into contact with the imprint material IM on the partial shot region on thee substrate. For this reason, the technique described below is used for an imprint process for a partial shot region, more specifically, a contact step. FIG. 6 illustrates the manner of performing a contact step of bringing the pattern region PR of the mold 1 into contact with the imprint material IM on the partial shot region on the substrate while the mold 1 is tiled outside the substrate 4 to shift the contact start position CP inwardly from the substrate. As shown in FIG. 5, in a full shot region the contact start position CP almost coincides with the pattern central position PC, and hence the reproducibility between full shot regions is high. Note, however, that as shown in FIG. 6, when the mold 1 is tilted, the lowermost point of the pattern region PR in the Z direction changes, and hence the position of the contact start position CP also changes. Accordingly, the manner of how the contact region between the imprint material IM and the pattern region PR is enlarged over the entire partial shot region, that is, the time-series change of the contact region (the filling path for the imprint material IM), differs from that in a full shot region. In a partial, shot region, the time-series change of the contact region is mainly associated with the posture (tilt) or shape of the pattern region PR of the mold 1.

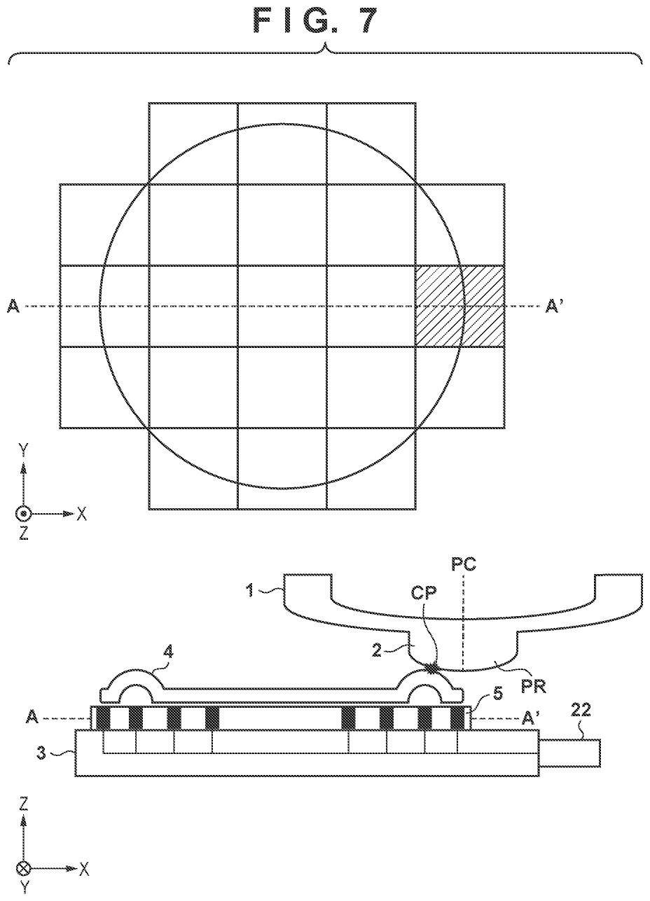

FIG. 7 illustrates the manner of performing a contact step of bringing the pattern region PR of the mold I into contact with the imprint material IM on a partial shot region on a substrate while part of the substrate 4 is deformed in a convex shape in the +Z direction by controlling the holding regions 2201 to 2204 of the substrate holding unit 5. When the substrate 4 is deformed in this manner, the uppermost point of the partial shot region in the Z direction changes, and hence the contact start position CP also changes. Accordingly, the manner of how the contact region between the imprint material IM and the pattern region PR is enlarged over the entire partial shot region, that is, the time-series change of the contact region (the filling path for the imprint material also differs from that in a full shot region. In this case, the time-series change of the contact region depends on both the posture (tilt) or shape of the pattern region PR of the mold 1 and the shape of the partial shot region on the substrate 4.

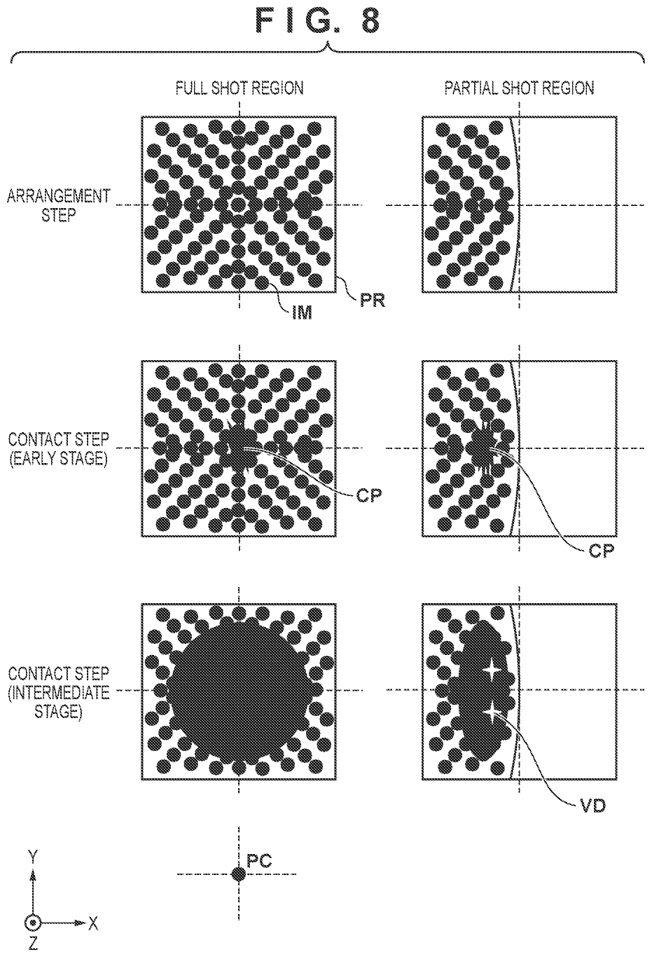

Described next is about the relationship between the layout (drop pattern) of droplets of the imprint material IM arranged on a shot region on the substrate 4 and the contact start position CP at which the pattern region PR of the mold 1 comes first into contact with the imprint material IM. FIG. 8 illustrates the behavior (state) of the imprint material IM in an arrangement step and a contact step in a full shot region in comparison with that in a partial shot region. FIG. 8 illustrates a case in which the same layout (the same drop pattern) of droplets of the imprint material IM is applied to a full shot region and a partial shot region. FIG. 8 also illustrates a contact step divided into a step (contact step (early stage)) of bringing the pattern region PR into contact with droplets of the imprint material IM and a step (contact step (intermediate stage)) of enlarging the contact region between the imprint material IM and the pattern region PR.

Referring to FIG. 8, the following is the way of thinking an arrangement step (the arrangement of droplets of the imprint material IM) for a full shot region. First of all, the pattern central position PC of the pattern region PR of the mold 1 is a starting point. In each of a plurality of local regions located in radiation directions from the pattern central position PC, the droplets of the imprint material IM are arranged such that the line density of droplets on lines parallel to directions orthogonal to the radiation directions is lower than the line density of droplets on lines parallel to the radiation directions.

Consider a case in which droplets of the imprint material IM are arranged for a partial shot region based on the way of thinking an arrangement step for a full shot region described above. In this case, since droplets of the imprint material IM cannot be arranged outside the substrate 4, the radial pattern of the droplets of the imprint material IM is cut into a semicircle-like pattern, as shown in FIG. 8. In addition, in a contact step (early stage), the contact start position CP of a full shot region is different from that of a partial shot region. In particular, in a partial shot region, the contact start position CP is located at a position different from the central position of the arrangement (layout) of droplets of the imprint material IM (that is, the central position of the arrangement of droplets of the imprint material IM is shifted from the contact start position CP).

Accordingly, in a contact step (intermediate stage), as the contact region between the imprint material IM and the pattern region PR is enlarged, a bubble defect VD occurs in a partial shot region, thereby interfering with the throughput.

Factors that cause the bubble defect VD in a partial shot region include the following. Although the starting point of the arrangement of droplets of the imprint material IM is the pattern central position PC, the contact start position CP does not coincide with the pattern central position PC, and the time-series change of the contact region (the filling path for the imprint material IM) differs from that in a full shot region. Accordingly, the starting point of the arrangement of droplets of the imprint material IM may be set to the contact start position CP at which the imprint material IM comes first into contact with the pattern region PR, and the layout of droplets of the imprint material IM may be determined in accordance with the time-series change of the contact region. This makes it possible to perform an imprint process for a partial shot region without reducing the throughput (that is, without causing any bubble defect VD).

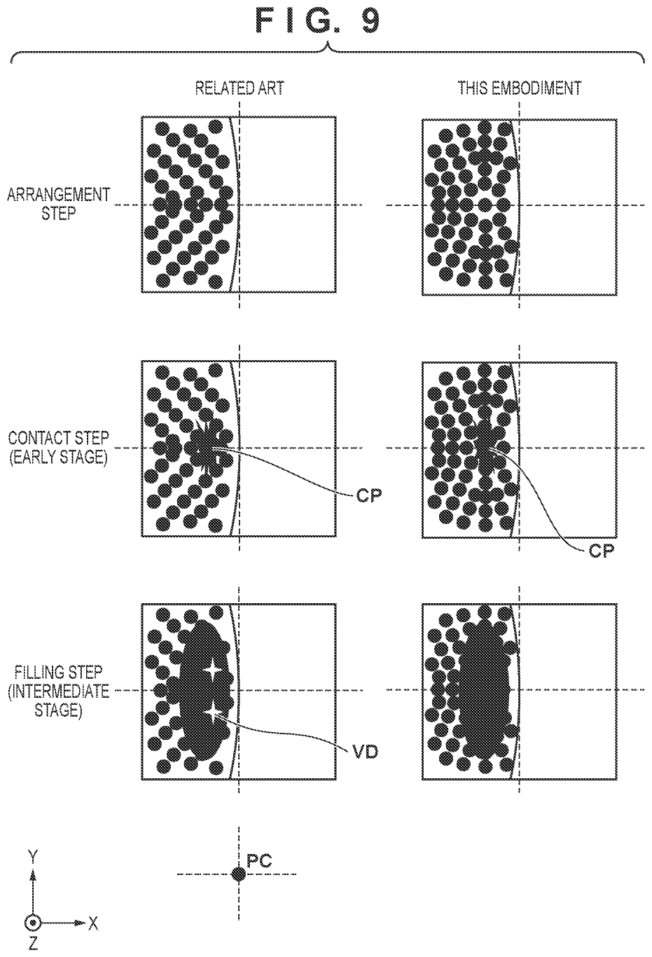

FIG. 9 comparatively illustrates the behaviors (states) of the imprint material IM in an arrangement step and a contact step for a partial shot region in each of the related art and this embodiment. In the related art, in an arrangement step, the manner of thinking an arrangement step for a full shot region described above is used to arrange droplets of the imprint material IM by regarding the pattern central position PC of the pattern region PR of the mold 1 as a starting point. In contrast to this, in the embodiment, in an arrangement step, the manner of thinking an arrangement step for a full shot region described above is not used, and droplets of the imprint material IM are arranged by regarding the contact start position CP at which the imprint material IM comes first into contact with the pattern region PR as a starting point. Referring to FIG. 9, in the embodiment, in a contact step (intermediate stage), there is no factor that hinders the enlargement of a contact region by pushing and spreading of the imprint material IM, and hence no bubble defect VD occurs and an imprint process can be performed without any reduction in throughput.

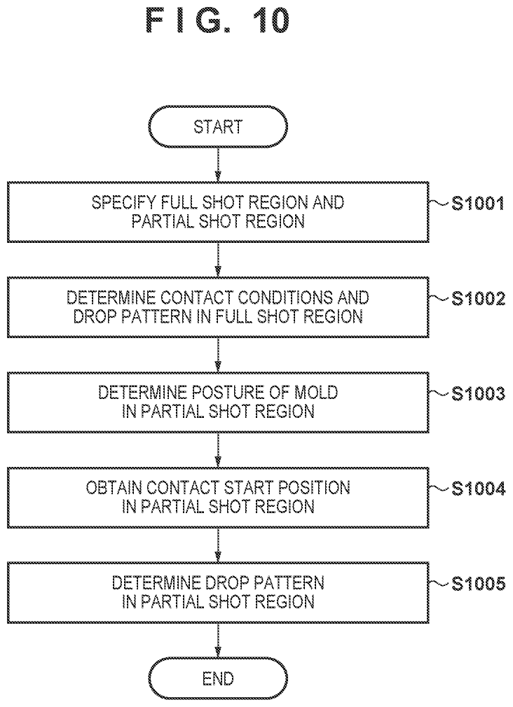

The following description will be made with reference to FIG. 10 about a method of determining the arrangement of droplets of the imprint material IM its this embodiment, that is, a drop pattern indicating the layout of droplets of the imprint, material IM to be arranged on a substrate. The control unit 18 of the imprint apparatus IMP or an information processing apparatus outside the imprint apparatus IMP may perform this determination method. Note that since the method of determining a drop pattern in a full shot region is the same as that in the related art, the following description will be focused on the method of determining a drop pattern in a partial shot region.

In step S1001, based on the layout of a. plurality of shot regions on a substrate, each of the plurality of shot regions is specified as a full shot region or a partial shot region. In other words, the plurality of shot regions on the substrate are specified as full shot regions each having the same area as that of the pattern region PR of the mold 1 and partial shot regions each having a smaller area than the pattern region PR of the mold 1.

In step S1002, contact conditions and a drop pattern in the full shot region specified in step S1001 are determined. The contact conditions are various conditions to be set when the pattern region PR of the mold 1 is brought into contact with the imprint material IM on the substrate, and include, for example, the shape and posture of the pattern region PR and the shape of each shot region on the substrate 4. In determining a drop pattern in the full shot region, the manner of thinking an arrangement step for a full shot region described above is used. More specifically, first of all, the pattern central position PC of the pattern region PR of the mold 1 is set to a starting point. A drop pattern is then determined such that in each of a plurality of local regions located in radiation directions from the pattern central position PC, the line density of droplets on lines parallel to directions orthogonal to the radiation directions is lower than the line density of droplets on lines parallel to the radiation directions.

In step S1003, the posture of the mold 1 is determined, which is to be set when the pattern region PR of the mold 1 is brought into contact, with the imprint material IM arranged in the partial shot region specified in step S1001, More specifically, the posture of the mold 1 is determined so as to prevent the mold 1 from coming into contact with the outermost peripheral region of a partial shot region in which no droplets of the imprint material are arranged, based on the shapes of the mold 1 and the substrate 4 when the imprint material IM is brought into contact with the pattern region PR. Note that the shape of the mold 1 includes a state in which the mesa portion 2 of the mold 1 and the pattern region PR are deformed by applying a force to the cavity 8. The shape of the substrate 4 includes a state in which part of the substrate 4 is deformed by controlling the holding regions 2201 to 2204 of the substrate holding unit 5.

In step S1004, the contact start position CP at which the pattern region PR of the mold 1 comes first into contact with the imprint material IM in the partial shot region is obtained based on the posture of the mold 1 determined in step S1003. The contact start position CP in the partial shot region can be obtained from, for example, a simulation using, as inputs, the posture of the mold 1 determined in step S1003 and the shape of the partial shot region (the position in the Z direction and the position in an XY plane).

In step S1005, a drop pattern in the partial shot region is determined based on the contact start position CP obtained in step S1004. More specifically, as shown in FIG. 9, a drop pattern is determined so as to arrange droplets of the imprint material IM at a plurality of positions along a plurality of different radiation directions from the contact start position CP, with the contact start position CP obtained in step S1004 serving as a starting point, In addition, a drop pattern is determined so as to satisfy the following condition in each of a plurality of local regions located in radiation directions from the contact start position CP.

The condition: The line density of the imprint material IM on lines on which a plurality of droplets of the imprint material IM are present parallel to directions orthogonal to the radiation directions is lower than the line density of the imprint material IM on lines on which a plurality of droplets of the imprint material IM are present parallel to the radiation directions.

In addition, a drop pattern in a partial shot region is preferably determined in consideration of the shape of the mold 1 and the shape of the substrate 4 when the pattern region PR is brought into contact with the imprint material IM, in addition to the above condition. Furthermore, a drop pattern in a partial shot region is preferably determined based on information representing, in a time-series manner, the enlargement of the contact region between the imprint material IM and the pattern region PR when the contact region is enlarged over the entire partial shot region. Note that information representing, in a time-series manner, the enlargement of the contact region can be obtained from, for example, a simulation using, as inputs, the shape and posture of the mold 1 and the shape of the partial shot region (the position in the Z direction and the position in an XY plane).

In this manner, this embodiment is configured to specify the contact start position CP in a partial shot region and determine a drop pattern so as to arrange droplets of the imprint material IM in radiation directions, with the contact start position CP serving as a starting point. This suppresses the confinement of gas in the space surrounded by the substrate 4 the imprint material LK and the mold 1 in a contact step (the generation of the bubble defect VD) and can prevent (reduce) a decrease in throughput. Therefore, according to the embodiment, it is possible to determine a drop pattern optimal for a partial shot region.

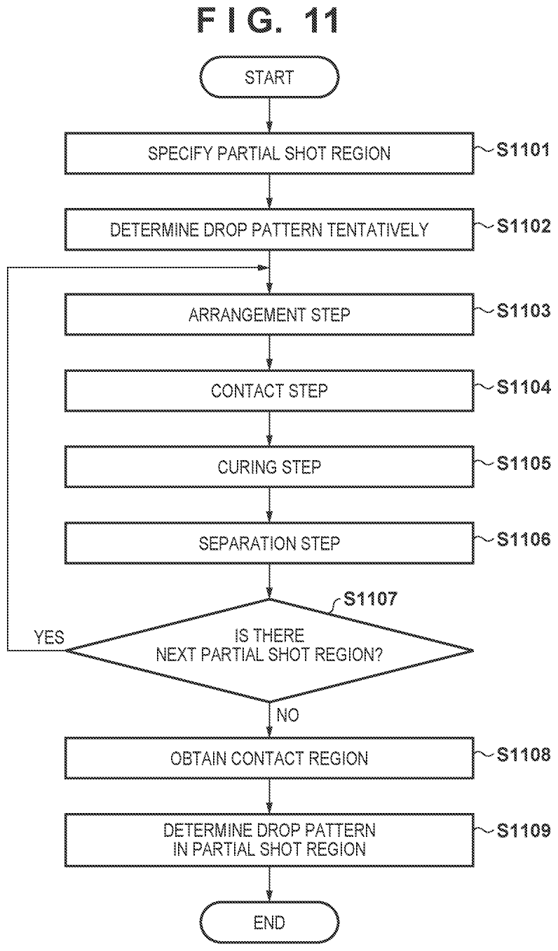

Note that the contact start position CP and information representing, in a time-series manner, the enlargement of a contact region may be obtained by observing the enlargement of the contact region upon actually bringing the mold 1 into contact with droplets of the imprint material IM tentatively arranged in a partial shot region. FIG. 11 is a flowchart for describing another determination method of determining to layout of droplets of the imprint material IM in this embodiment, that is, a drop pattern indicating the layout of droplets of the imprint material IM which are to be arranged on the substrate. The following, description will be focused on the method of determining a drop pattern in a partial shot region.

In step S1101, a partial shot region is specified from a plurality of shot regions on a substrate based on the layout of the plurality of shot regions on the substrate.

In step S1102, the layout of droplets of the imprint material IM which are to be arranged in the partial shot region specified in step S1101, that is, a drop pattern in the partial shot region, is tentatively determined.

In step S1103, an arrangement step is performed so as to arrange droplets of the imprint material IM in the partial shot region in accordance with the drop pattern tentatively determined in step S1102.

In step S1104 a contact step is performed so as to bring the pattern region PR of the mold 1 into contact with the imprint material IM on part of the partial shot region and then enlarge the contact region between the imprint material IM and the pattern region PR over the entire partial shot region. In a contact step, the image capturing unit 14 captures an image depicting how the contact, region enlarges over the entire partial shot region after the pattern region PR of the mold 1 comes into contact with the imprint material IM.

In step S1105, a curing step is performed so as to cure the imprint material IM while the pattern region PR of the mold 1 is in contact with the imprint material IM on the partial shot region.

In step S1106, separation step is performed so as to separate the pattern region PR of the mold 1 from the cured imprint material IM on the partial shot region (separate the mold 1 from the cured imprint material IM).

In step S1107, it is determined whether there is any partial shot region for which steps S1103 to S1106 are to be performed. If there is a next partial shot region, the process shifts to step S1103. If there is no next partial shot region, the process shifts to step S1108.

Step S1108 is performed to obtain an image depicting how the contact region between the imprint material IM and the pattern region PR of the mold 1 which is image-captured by the image capturing unit 14 in the contact step (S1104), enlarges, that is, information indicating, in a time-series manner, the enlargement of the contact region.

In step S1109, a drop pattern in the partial shot region is determined based on the information indicating, in a time-series manner the enlargement of the contact region obtained in step S1108. More specifically, first of all, the contact start position CP at which the pattern region PR of the mold 1 comes first into contact with the imprint material IM in the partial shot region is obtained from the information indicating, in a time-series manner, the enlargement of the contact region. As in step S1005, a drop pattern is then determined so as to arrange droplets of the imprint material IM at a plurality of positions along a plurality of different radiation directions from the contact start position CP, with the contact start position CP serving, as a starting point.

As described above, the contact start position CP in the partial shot region may be specified from the result of actually observing how the contact region between the imprint material IM and the pattern region PR of the mold 1 enlarges.

The imprint apparatus IMP performs an arrangement step of arranging droplets of the imprint material IM on a substrate in accordance with the drop pattern determined in the above manner, and then performs a contact step, a curing step, and a separation step. As described above, in this embodiment, a drop pattern is determined so as to suppress the confinement of gas in the space surrounded by the substrate 4, the imprint material IM, and the mold 1 (the occurrence of the bubble defect VD) in a partial shot region. Therefore, the imprint apparatus IMP can prevent a reduction in throughput in a partial shot region and improve the throughput as a whole.

The pattern of a cured product formed using the imprint apparatus IMP is used permanently for at least some of various kinds of articles or temporarily when manufacturing various kinds of articles. The articles are an electric circuit element, an optical element, a MEMS, a recording element, a sensor, a mold, and the like. Examples of the electric circuit element are volatile and nonvolatile semiconductor memories such as a DRAM, a SRAM, a flash memory, and a MRAM and semiconductor elements such as an LSI, a CCD, an image sensor, and an FPGA. Examples of the mold are molds for imprint.

The pattern of the cured product is directly used as the constituent member of at least some of the above-described articles or used temporarily as a resist mask. After etching or ion implantation is performed in the substrate processing step, the resist mask is removed.

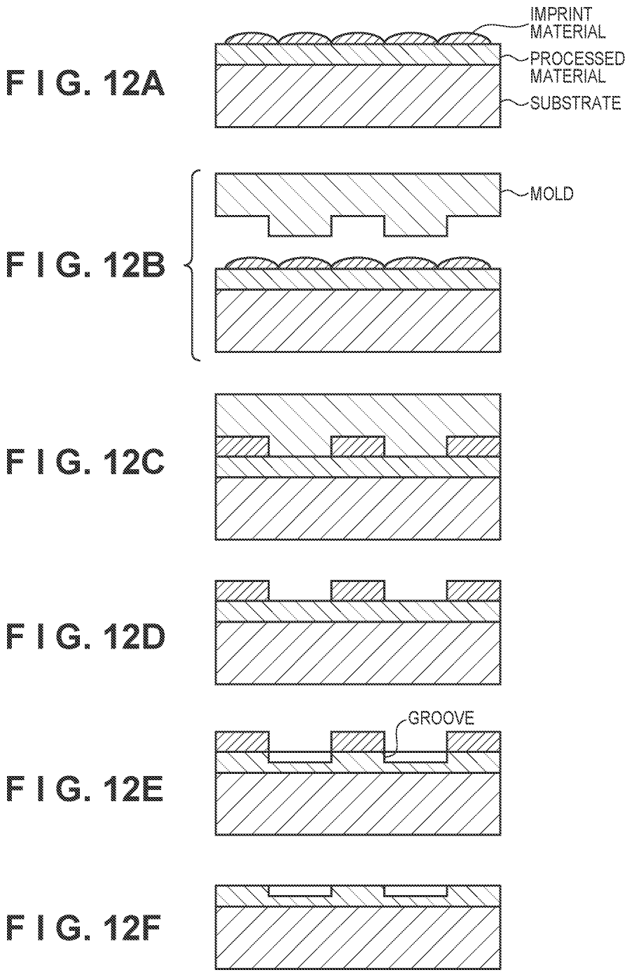

Next, description regarding a detailed method of manufacturing an article is given. As illustrated in FIG. 12A, the substrate such as a silicon wafer with a processed material such as an insulator formed on the surface is prepared. Next, an imprint material is applied to the surface of the processed material by an inkjet method or the like. A state in which the imprint material is applied as a plurality of droplets onto the substrate is shown here.

As shown in FIG. 12B, a side of the mold for imprint with a projection and groove pattern is formed on and caused to face the imprint material on the substrate. As illustrated in FIG. 12C, the substrate to which the imprint material is, applied is brought into contact with the mold, and a pressure is applied. The gap between the mold and the processed material is filled with the imprint material. In this state, when the imprint material is irradiated with light serving as curing energy through the mold, the imprint material is cured.

As shown in FIG. 12D, after the imprint material is cured, the mold is released from the substrate. Thus, the pattern of the cured product of the imprint material is formed on the substrate. In the pattern of the cured product, the groove of the mold corresponds to the projection of the cured product, and the projection of the mold corresponds to the groove of the cured product. That is, the projection and groove pattern of the mold 4z is transferred to the imprint material.

As shown in FIG. 12E, when etching is performed using the pattern of the cured product as an etching resistant mask, a portion of the surface of the processed material where the cured product does not exist or remains thin is removed to form a groove. As shown in FIG. 12F, when the pattern of the cured product is removed, an article with the grooves formed in the surface of the processed material can be obtained. The pattern of the cured material is removed here, but, for example, the pattern may be used as a film for insulation between layers included in a semiconductor element or the like without being removed after processing, in other words as a constituent member of the article.

Embodiment(s) of the present invention can also be realized by a computer of a system or apparatus that reads out and executes computer executable instructions (e.g., one or more programs) recorded on a storage medium (which may also be referred to more fully as a ‘non-transitory computer-readable storage medium’) to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)™), a flash memory device, a memory card, and the like.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2020-039217 filed on Mar. 6, 2020, which is hereby incorporated by reference herein in its entirety.

What is claimed is:

1. A determination method of determining a drop pattern indicating a layout of droplets of an imprint material to be arranged on a substrate and used in an imprint apparatus which forms a pattern of the imprint material on the substrate by using a mold, the method comprising:
specifying a partial shot region of the plurality of shot regions which has a smaller area than a pattern region of the mold based on a layout of a plurality of shot regions on the substrate;
determining a posture of the mold when the mold is brought into contact with the imprint material arranged in the partial shot region specified in the specifying;
obtaining a contact start position at which the mold comes first into contact with the imprint material in the partial shot region based on the posture of the mold determined in the determining the posture; and
determining the drop pattern in the partial shot region so as to arrange droplets of the imprint material at a plurality of positions respectively, located along a plurality of different radiation directions from the contact start position, with the contact start position obtained in the obtaining serving as a starting point.

2. The method according to claim 1 wherein in the determining the drop pattern, the drop pattern in the partial shot region is determined such that in each of a plurality of local regions located in radiation directions from the contact start position, a line density of the imprint material on lines on which a plurality of droplets of the imprint material are present and which are parallel to directions orthogonal to the radiation directions is lower than a line density of the imprint material on lines on which a plurality of droplets of the imprint material are present and which are parallel to the radiation directions.

3. The method according to claim 1, wherein in the determining the drop pattern, the drop pattern in the partial shot region is determined based on a shape of the mold and a shape of the substrate when the mold is brought into contact with the imprint material arranged in the partial shot region.

4. The method according to claim 1, wherein in the determining the drop pattern, the drop pattern in the partial shot region is determined based on information indicating, in a time-series manner, enlargement of a contact region between the imprint material and the pattern region after the mold is brought into contact with the imprint material arranged in the partial shot region when the contact region is enlarged over the entire partial shot region.

5. The method according to claim 4, further comprising, before the determining the drop pattern, obtaining the information by observing enlargement of the contact region upon actually bringing the mold into contact with the imprint material tentatively arranged in the partial shot region.

6. The method according to claim 1, wherein in the determining the posture, a posture of the mold is determined so as to prevent the mold from coming into contact with an outermost region of the partial shot region on which the imprint material is not arranged.

7. The method according to claim 6, wherein in the determining the posture, a posture of the mold is determined based on a shape of the mold and a shape of the substrate when the mold is brought into contact with the imprint material arranged in the partial shot region.

8. An imprint method of forming a pattern of an imprint material on a substrate by using a mold, the method comprising:
determining a drop pattern indicating a layout of droplets of the imprint material to be arranged on the substrate;
arranging droplets of the imprint material on the substrate in accordance with the drop pattern determined in the determining the drop pattern;
wherein determining the drop pattern
specifying a partial shot region of the plurality of shot regions which has a smaller area than a pattern region of the mold based on a layout of a plurality of shot regions on the substrate;
determining a posture of the mold when the mold is brought into contact with the imprint material arranged in the partial shot region specified in the specifying;
obtaining a contact start position at which the mold comes first into contact with the imprint material in the partial shot region based on the posture of the mold determined in the determining the posture; and
determining the drop pattern in the partial shot region so as to arrange droplets of the imprint material at a plurality of positions respectively located along a plurality of different radiation directions from the contact start position, with the contact start position obtained in the obtaining serving, as a starting point.

9. An imprint apparatus which forms a pattern of an imprint material on a substrate by using a mold, the apparatus comprising:
a control unit configured to perform processing of determining a drop pattern indicating a layout of droplets of the imprint material to be arranged on the substrate; and
an arranging unit configured to arrange droplets of the imprint material on the substrate based on the drop pattern determined in the processing,
wherein the processing includes
specifying a partial shot region of a plurality of shot regions on the substrate which has a smaller area than thee pattern region of the mold based on a layout of the plurality of shot regions,
determining a posture of the mold when the mold is brought into contact with the imprint material arranged in the specified partial shot region,
obtaining a contact start position at which the mold comes first into contact with the imprint material in the partial shot region based on the determined posture of the mold, and
determining the drop pattern in the partial shot region so as to arrange droplets of the imprint material at a plurality of positions respectively located in a plurality of different radiation directions from the obtained contact start position, with the contact start position serving as a starting point.

10. An article manufacturing method comprising:
forming a pattern on a substrate using an imprint apparatus defined in claim 9;
processing the substrate on which the pattern is formed in the forming; and
manufacturing an article from the processed substrate.

11. A non-transitory storage medium storing a program for causing a computer to execute a determination method of determining a drop pattern indicating a layout of droplets of an imprint material to be arranged on a substrate and used in an imprint apparatus which forms a pattern of the imprint material on the substrate by using a mold, the method comprising:
specifying a partial shot region of the plurality of shot regions which has a smaller area than a pattern region of the mold based on a layout of a plurality of shot regions on the substrate;
determining a posture of the mold when the mold is brought into contact with the imprint material arranged in the partial shot region specified in the specifying;
obtaining a contact start position at which the mold comes first into contact with the imprint material in the partial shot region based on the posture of the mold determined in the determining the posture; and
determining the drop pattern in the partial shot region so as to arrange droplets of the imprint material at a plurality of positions respectively located along a plurality of different radiation directions from the contact start position, with the contact start position obtained in the obtaining serving as a starting point.
